(19) United States
(12) Patent Application Publication
(10) Pub. No.: US 2007/0117350 A1
(43) Pub. Date: May 24, 2007

(54) STRAINED SILICON ON INSULATOR (SSOI) WITH LAYER TRANSFER FROM OXIDIZED DONOR

(75) Inventors: Michael R. Seacrist, St. Peters, MO (US); Lu Fei, St. Peters, MO (US)

Correspondence Address: SENNIGER POWERS, ONE METROPOLITAN SQUARE, 16TH FLOOR, ST LOUIS, MO, 63102, US

(73) Assignee: MEMC ELECTRONIC MATERIALS, INC., St. Peters, MO (US)

(21) Appl. No.: 11/616,517

(22) Filed: Dec. 27, 2006

Related U.S. Application Data
(63) Continuation-in-part of application No. 11/461,653, filed on Aug. 1, 2006.
(60) Provisional application No. 60/705,039, filed on Aug. 3, 2005.

(51) Int. Cl. H01L 27/12; H01L 21/30

(52) U.S. Cl. 438/459; 257/347

(57) ABSTRACT

This invention generally relates to a strained silicon on insulator (SSOI) structure, and to a process for making the same. The process includes forming a thin SiO₂ layer on a strained silicon layer after it is formed on the donor wafer and before bonding to the handle wafer.

### REFERENCE TO RELATED APPLICATIONS

This application is a continuation-in-part of pending U.S. patent application Ser. No. 11/461,653, filed Aug. 1, 2006, which claims priority from U.S. Provisional Application Ser. No. 60/705,039 filed on Aug. 3, 2005, the entire disclosures of which are incorporated herein by reference.

### FIELD OF THE INVENTION

The present invention relates generally to a strained silicon on insulator (SSOI) structure. More particularly, the present invention is directed to a SSOI structure with an improved bond interface between the strained silicon layer and the handle wafer. The present invention is further directed to a process for making such a structure.

### BACKGROUND OF THE INVENTION

Silicon on insulator (SOI) structures generally comprise a handle wafer, a semiconductor device layer, and a dielectric insulating layer between the handle wafer and the device layer. By insulating the device layer from the handle wafer of the SOI structure, the device layer yields reduced leakage currents and lower capacitance. Strained silicon on insulator (SSOI) structures for semiconductor devices combine these benefits of SOI technology with strained silicon technology, with the strained silicon layer providing enhanced carrier mobility.

The strained silicon on insulator structure may be fabricated or manufactured in a number of ways. For example, in one approach, a relaxed silicon-germanium (SiGe) layer is formed on an insulator by one of several techniques known in the art, such as: (i) separation by implantation of oxygen (known as “SIMOX”, see, e.g., U.S. Pat. No. 5,436,175); (ii) wafer bonding followed by back etching; (iii) wafer bonding followed by hydrogen exfoliation layer transfer; or (iv) recrystallization of amorphous material. This is followed by the epitaxial deposition or growth of a strained silicon layer on the SiGe layer. The relaxed SiGe-on-insulator layer serves as the template for inducing strain in the Si layer, the induced strain typically being greater than approximately 10⁻³.

Such a structure has limitations, however. For example, it is not conducive to the production of fully-depleted strained semiconductor on insulator devices in which the layer over the insulating material must be thin enough (e.g., less than 300 angstroms) to allow for full depletion of the layer during device operation. Additionally, the relaxed SiGe layer adds to the total thickness of the layer over the insulating material, and thus makes it difficult to achieve the thicknesses required for fully depleted silicon on insulator device fabrication.

Such problems may be alleviated if the strained SOI structure has the strained Si layer disposed directly on the insulating material. (See, e.g., published U.S. patent application No. 2004/0005740). This may be achieved, for example, by utilizing both wafer bonding and separation by implantation techniques. Specifically, a relaxed layer of, for example, SiGe may be formed on the surface of one wafer or substrate. A strained silicon layer may then be formed by, for example, epitaxial deposition, on the surface of the relaxed layer. Hydrogen ions may then be implanted into the relaxed layer to define a cleave or separation plane therein according to any technique generally known in the art, such as for example the process disclosed in U.S. Pat. No. 6,790,747. The resulting structure may then be bonded to a second wafer or substrate, having a dieletric insulating layer on the surface thereof, with the surface of the strained layer being bound to the dieletric layer surface. Once bound, the resulting structure may then be separated along the cleave or separation plane, to yield a strained silicon on insulator structure.

Preparing an SSOI structure in this way is not without problems, however. With the bond interface between the surface of the strained silicon layer and the dielectric layer surface, the strained silicon layer displays some undesirable electronic properties. Such properties may be the result of impurities that tend to collect along the bond interface, which may subsequently diffuse into the strained silicon layer.

### SUMMARY OF THE INVENTION

Briefly, therefore, the present invention is directed to a process for preparing a strained silicon on insulator structure comprising a handle wafer, and a strained silicon layer, the process comprising forming a thin layer of SiO₂ on the strained silicon layer before bonding the silicon layer to the handle wafer.

More particularly, the present invention is directed to a process for preparing a strained silicon on insulator structure, the process comprises: (i) forming a relaxed silicon-comprising layer on a surface of a donor wafer; (ii) forming a strained silicon layer on a surface of the relaxed silicon-comprising layer; (iii) forming a thin layer of silicon dioxide (i.e., SiO₂) on a surface of the strained silicon layer; (iv) bonding a surface of the thin silicon dioxide layer on the donor wafer to the handle wafer to form a bonded wafer, wherein a bond interface is formed between the silicon dioxide layer and the handle wafer; (v) separating the bonded wafer along a separation plane within the relaxed silicon-comprising layer to transfer the strained silicon layer to the handle wafer, the strained silicon layer on said handle wafer having a residual relaxed silicon-comprising layer on the surface thereof; and, (vi) substantially removing the residual relaxed silicon-comprising layer from the strained silicon layer.

Furthermore, the present invention is directed to a single crystal silicon structure comprising a single crystal silicon substrate having a central axis, a front side and a back side which are generally perpendicular to the central axis, a circumferential edge, a radius extending from the central axis to the circumferential edge. The single crystal silicon structure also comprises (i) a relaxed silicon-comprising layer disposed on the front surface of the silicon substrate; (ii) a strained silicon layer disposed on the relaxed silicon-comprising layer; and (iii) a layer of SiO₂ disposed on the strained silicon layer.

Other objects and features of this invention will be in part apparent and in part pointed out hereinafter.

### BRIEF DESCRIPTION OF THE DRAWINGS

FIG. 1A is a cross-sectional, schematic drawing of a donor wafer 12 having a relaxed silicon-comprising layer 13 on a surface thereof, a strained silicon layer 14, and a SiO₂ layer 19. Dashed line 17 in the relaxed silicon-comprising layer 13 represents a separation or cleave plane, present therein.

FIG. 1B is a cross-sectional, schematic drawing of a handle wafer 16 comprising an optional dielectric layer 15 disposed on a surface thereof, prior to bonding with the wafer of 1A.

FIG. 2 is a cross-sectional, schematic drawing of a bonded structure 20, resulting from contacting the surface of the SiO₂ layer 19 of the donor wafer (illustrated in FIG. 1A) to the surface of the optional dielectric layer 15 of the handle wafer (illustrated in FIG. 1B).

FIG. 3 is a cross-sectional, schematic drawing which illustrates separation of the bonded structure 20 along the separation or cleave plane 17 in the relaxed silicon-comprising layer 13, and thus the transfer of the silicon dioxide layer 19 and the strained silicon layer 14, with a residual portion of the relaxed silicon-comprising layer 33 that may optionally be present thereon, onto the optional dielectric layer 15 of handle wafer 16.

FIG. 4 is a cross-sectional, schematic drawing of the strained silicon on insulator structure of the present invention 40.

Corresponding reference characters indicate corresponding parts throughout the drawings.

### DETAILED DESCRIPTION OF THE PREFERRED EMBODIMENTS

The present invention is directed to an improved strained silicon on insulator (SSOI) structure, wherein the SSOI structure is prepared by forming a thin silicon dioxide (SiO₂) layer on a strained silicon layer before bonding the SiO₂ layer to a handle wafer, or optionally to a dielectric layer on a handle wafer. Without being held to a particular theory, it is generally believed that the SSOI structure may be advantageous because it may exhibit improved electrical performance of devices formed in the strained silicon (as compared, for example, to a device formed in the strained silicon of a structure wherein the strained silicon layer was bonded directly to the optional dielectric layer on a handle wafer). Also, the present SSOI structure advantageously moves any impurities bound at the bond interface (between the thin SiO₂ layer and the handle wafer) further away from the strained silicon layer.

In accord with the invention, the semiconductor material may be any material generally known in the art suitable for semiconductor applications, such as a silicon-comprising material. For exemplary purposes herein, the semiconductor material is silicon being utilized in an SSOI structure.

It is to be noted that the thin SiO₂ layer on the strained silicon layer of the donor wafer is readily integrated into known processes of making SSOI structures. Such processes include, e.g., the aforementioned process of U.S. Pat. No. 6,790,747, as well as the wafer bonding and layer transfer techniques described in U.S. patent application Publication Nos. 2004/0005740 and 2004/0031979, the entire contents of which are incorporated herein by reference for all relevant purposes. Accordingly, essentially any of the techniques generally known for preparing a SSOI structure may be employed in accordance with the present invention. Preferably, the process of the present invention utilizes wafer bonding and layer transfer techniques. The present invention will therefore be set forth in greater detail below in the context of these techniques. It is to be understood, however, that this is for purposes of illustration and should not be viewed in a limiting sense. It is to be further understood that, in the practice of the present invention, these techniques may be suitably carried out using a variety of apparatus and process conditions well-known in the art and, in some instances, may be omitted or combined with other techniques and conditions without departing from the scope of the present invention.

1. Formation of the Strained Silicon Layer

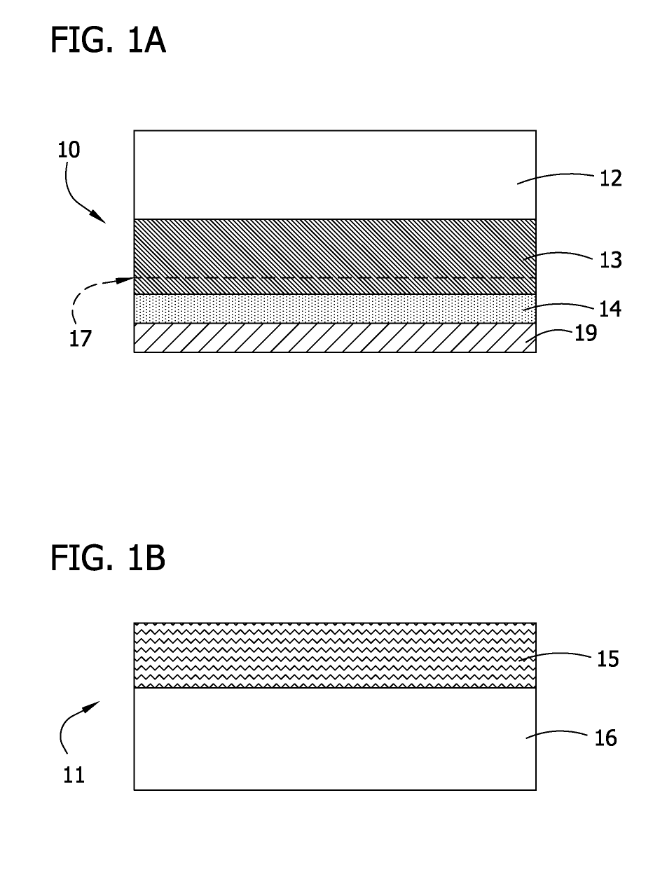

While many techniques may be used to form the SSOI structure, for purposes of illustration of some of the preferred embodiments of the present invention, a process for preparing a SSOI structure by means of wafer bonding and layer transfer techniques will be described herein in greater detail, with reference to FIGS. 1-4. Generally speaking, these techniques comprise the preparation of two separate structures, bonding them together along a bond interface, and then cleaving them along a separation plane that is different from the bond interface and that has been formed via an implantation technique. Each structure comprises a substrate or supporting wafer, which may be made of quartz or sapphire, but more commonly comprises a semiconductor material, such as silicon (e.g., single crystal silicon, prepared for example in accordance with the Czochralski method), germanium, or silicon-germanium (SiGe). In one preferred embodiment, the substrates comprise a single crystal silicon wafer, the wafer having a diameter of at least about 150 mm, 200 mm, 300 mm, or more.

One substrate will be referred to hereinafter as a “handle wafer.” The handle wafer has an optional dielectric layer directly disposed on a surface thereof, and serves as the substrate for the final SSOI structure. The other substrate will be referred to hereinafter as a “donor wafer.” The donor wafer has a relaxed silicon-comprising layer that is directly disposed on a surface thereof and serves as the substrate upon which the strained silicon layer is formed prior to a wafer bonding step.

A. Donor Wafer Structure

Referring now to FIG. 1A, the donor wafer structure 10 comprises a donor wafer or substrate 12, a relaxed silicon-comprising layer 13 on a surface thereof having a lattice constant different than that of a relaxed silicon lattice, and a strained silicon layer 14 on a surface of the relaxed silicon-comprising layer. In one preferred embodiment, the silicon-comprising layer is SiGe. The specific composition of the relaxed SiGe layer may vary according to the desired level of lattice strain to be induced in the strained silicon layer. Typically, the SiGe layer comprises at least about 10% Ge, and in some instances may comprise about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 35%, with a concentration of about 20% Ge being preferred.

Essentially any technique generally known in the art may be used to form the relaxed silicon-comprising (e.g., SiGe) layer, such as one of the known epitaxial deposition techniques. Generally speaking, the thickness of the relaxed layer is sufficient to permit substantially full plastic relaxation of the SiGe crystal lattice. Typically, the relaxed layer has a substantially uniform thickness, the average thickness thereof being at least about 0.1 microns, such as at least about 0.5 microns, at least about 1.0 micron, and even at least about 2.0 microns. Alternatively, it may be desirable to express thickness in terms of a range. For example, the average thickness may typically be in the range of from about 0.1 microns to about 2.0 microns, such as from about 0.5 micron to about 1.0 micron. In one preferred embodiment, the SiGe layer has an average thickness of about 2.0 microns. It is to be noted that the ranges and minimum thickness values set forth above are not narrowly critical to the invention, so long as the thickness is sufficient to permit substantially full plastic relaxation of the crystal lattice of the relaxed layer.

A strained layer 14 of, for example, silicon is formed or deposited on the relaxed (e.g., SiGe) layer 13, where the strain results from the difference in lattice constants between, for example, the strained Si layer and the relaxed SiGe layer. Such strain consequently alters the crystallinity of the silicon of the strained layer.

Like the relaxed layer, essentially any technique generally known in the art may be used to form or deposit the strained layer on the relaxed layer, provided strain is present in the layer after deposition thereof. In one preferred embodiment, one of the known epitaxial deposition techniques (e.g., atmospheric-pressure chemical vapor phase deposition (APCVD); low- or reduced-pressure CVD (LPCVD); ultra-high-vacuum CVD (UHVCVD); molecular beam epitaxy (MBE); or, atomic layer deposition (ALD)), is used wherein by chemical vapor deposition, for example, silane, disilane, or trislane are deposited. The epitaxial growth system may comprise a single-wafer or a multiple-wafer batch reactor. The strained layer may be formed at a relatively low temperature, e.g., less than 700° C., possibly in order to promote a defined interface between the strained layer and the relaxed layer. A defined interface may enhance the subsequent separation or removal of the strained layer from the relaxed layer. In an embodiment in which the strained layer contains substantially 100% Si, this layer may be formed in a dedicated chamber of a deposition tool that is not exposed to, for example, a Ge source gas. By doing so, cross-contamination is avoided and a higher quality interface is promoted between the strained layer and relaxed layer. Additionally, the strained layer may be formed from an isotopically pure silicon precursor, which has better thermal conductivity than conventional Si. Higher thermal conductivity may help dissipate heat from devices subsequently formed on the strained layer, thereby maintaining the enhanced carrier mobilities provided by the strained layer.

Generally speaking, the strained layer 14 is grown to a substantially uniform thickness which is sufficient for subsequent device fabrication, but not thick enough for the crystal lattice at the exposed silicon surface to undergo significant plastic relaxation. Typically, therefore, the strained layer is grown to an average thickness of at least about 1 nm, such as between about 1 nm and about 100 nm, preferably between about 10 nm and about 80 nm, and more preferably between about 15 nm and about 40 nm. In one preferred embodiment, the average thickness of the silicon layer is about 20 nm.

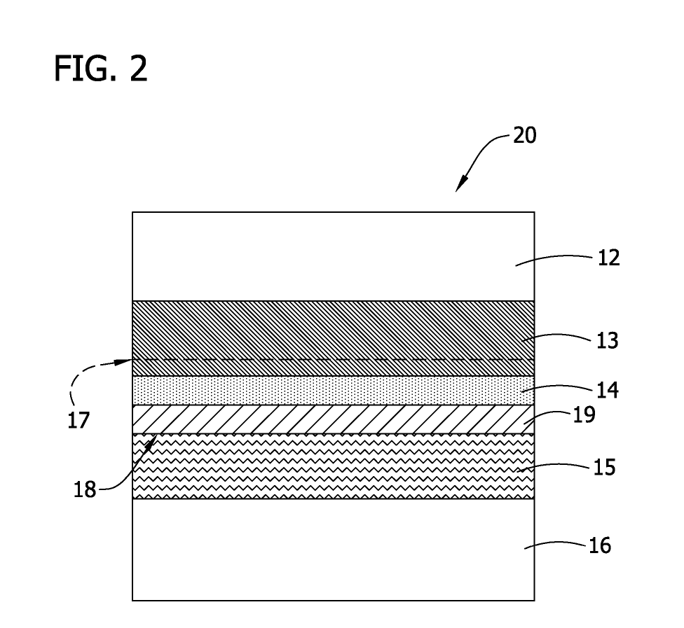

After the strained silicon layer is formed on the donor wafer, a thin layer of silicon dioxide 19 is formed on the strained silicon layer 14. The thin layer of SiO₂ is formed using means known in art for oxide formation, such as thermal oxidation and chemical vapor deposition (CVD). While thermal oxidation will be referred to hereinafter as the illustrative example, it should be understood that other oxide formation techniques may be employed in accord with the invention. The presence of this SiO₂ layer results in a change in the location of a bond interface 18 (as shown in FIG. 2) between the donor wafer structure and the handle wafer structure (as shown in FIG. 1B, and as further detailed herein below), as compared to the conventional practice of bonding the handle and donor wafers during SOI formation to create a bond interface between the surface of the strained silicon layer 14 of the donor wafer and the surface of the optional dielectric layer 15 of the handle wafer.

According to the present invention, a bond interface 18 is created between a surface of the thin layer of SiO₂ 19 on the donor wafer structure and a surface of the handle wafer, and in particular to a surface of an optional dielectric layer 15 present on the handle wafer structure (as described further herein below). Without being held to a particular theory, it is generally believed that by creating the bond interface between a thin layer of SiO₂ on the strained silicon layer and the handle wafer, which may optionally have a dielectric layer on the surface thereof, the SSOI structure may exhibit improved electrical properties. There is also believed to be a diminished likelihood of damaging the strained silicon layer as a result of the bonding step, as compared to the results obtained from a process wherein a surface of the strained silicon layer is bonded directly to the handle wafer, or optionally a dielectric layer present on the handle wafer, at least in part because there is no mechanical bond interface between the strained silicon layer and the handle wafer. Furthermore, the expected improvement in electrical properties is believed to result from the fact that impurities tend to collect at the bond interface and, when the bond interface is located directly adjacent to the strained silicon layer, these impurities may subsequently migrate into the strained silicon layer. The presence of the SiO₂ layer thus acts to limit, if not prevent, this migration.

It is believed that, to-date, strained silicon has not been subjected to a process to form a layer of silicon dioxide thereon because the metastable strained silicon relaxes at elevated temperatures. For example, a typical thermal oxidation process known in the art may subject silicon to 1000° C., which is sufficient to induce relaxation in the strained silicon layer. Furthermore, some processes, such as thermal oxidation of the strained silicon layer, actually consume the strained layer. Given that the strained layer is typically very thin, precise control of the thermal oxidation process to avoid over (or total) consumption of the strained silicon layer was difficult.

Surprisingly, and in accordance with the present invention, the thin layer of SiO₂ can be successfully formed without relaxation, and/or over consumption, of the of the metastable strained silicon layer. This is accomplished by subjecting the strained silicon layer to an oxide formation process under relatively mild thermal conditions, which involve processing the strained silicon at a temperature below the temperature at which strained silicon relaxes for a sufficient time to form a layer of SiO₂ of sufficient thickness (i.e., a thickness sufficient to achieve the desired bond interface strength and/or the desired improved electrical properties). Specifically, the oxide formation process is carried out below 1000° C. in order to avoid relaxation of the strained layer, but at a temperature which is sufficient to form an oxide on the surface of the strained silicon layer. For example, in the thermal oxidation embodiment, an anneal may typically be carried out below about 900° C. or 850° C., and above about 400° C., such as above about 600° C., 700° C., or 800° C., the temperature of the anneal being for example between about 400° C. and less than 1000° C., between about 600° C. and about 900° C., or between about 700° C. and about 850° C. In one particular embodiment, the anneal is carried out between about 800° C. and about 850° C.

The specific time of the oxide formation process is typically not critical to carrying out the invention, so long as processing is carried out for a time sufficient to form a continuous layer of SiO₂ on the strained silicon layer. Generally speaking, consistent with the considerations noted above, the time is less than the time that would lead to relaxation or over consumption of the strained silicon layer. For example, in the thermal oxidation embodiment when the anneal is carried out in a steam atmosphere (i.e., wet oxidation), the anneal may be carried out for at least about 100 seconds, at least about 200 seconds, or at least about 300 seconds. Furthermore, the anneal is typically carried out for less than about 2000 seconds, less than about 1000 seconds, or less than about 600 seconds. For example, in one preferred embodiment, the anneal is carried out for between about 200 and about 1000 seconds, or between about 300 and about 600 seconds.

The final thickness of the layer of SiO₂ formed on the strained silicon layer is typically optimized to achieve the desired bond strength and/or electronic properties, while still providing a strained silicon layer of sufficient thickness for device fabrication. For example, the layer of SiO₂ is generally as thick as possible without relaxing the metastable strained silicon layer, while retaining an adequate thickness of the strained silicon layer for subsequent device formation therein.

In this regard it is to be noted that the layer of SiO₂ is formed in the thermal oxidation embodiment by exposing the strained silicon layer 14 to an oxygen-comprising atmosphere at a temperature and for a duration as detailed above, wherein during this anneal the exposed surface of the strained silicon layer forms SiO₂ by consuming about 1 angstrom (Å) of strained silicon to form about 2 Å of SiO₂. Accordingly, the resulting thickness of the SiO₂ layer is at least in part a function of the initial thickness of the strained silicon layer, and more particular is some fraction thereof (e.g., about one-tenth thereof, about one-fifth thereof, or about one-third thereof). Typically, however, the layer of SiO₂ has an average thickness of at least about 50 Å, at least about 100 Å, at least about 150 Å, or at least about 200 Å, and less than about 350 Å, about 300 Å, or about 250 Å. In some particular embodiment, the average thickness may for example fall within the range of between about 50 and about 350 Å, or between about 100 and about 300 Å, or between about 150 and about 250 Å.

Referring again to FIG. 1A, in order to achieve subsequent transfer of the strained silicon layer, ions, such as hydrogen ions, may be implanted into the relaxed layer 13 at a substantially uniform depth. The ions are typically implanted into the relaxed layer after strained layer 14 and SiO₂ layer 19 have been formed, the ions thus being implanted through the SiO₂ layer and the strained layer and into the relaxed layer. This ion implantation defines a separation or cleave plane 17 in the relaxed layer. Preferably, ions are implanted to an average depth that is sufficient to ensure a satisfactory transfer of the strained layer upon a subsequent thermal treatment, while limiting the amount of relaxed layer transferred therewith as much as possible. Typically, as further detailed herein below, the ions are implanted at least about 20, 30, 40 or even 50 nm, or more into the relaxed layer. For example, in some instances the ions are implanted at least about 65 nm, 75 nm, 85 nm, 100 nm, 150 nm, 200 nm or more into the relaxed layer. Ion implantation may be achieved using means known in the art. For example, this implantation may be achieved in a manner according to the process of U.S. Pat. No. 6,790,747. Implantation parameters may include, for example, implantation of hydrogen ions (H⁺) to a dose from about 1 to about 5×10¹⁶ ions/cm² at an energy of, for example, about 20 to about 100 keV (e.g., H⁺ may be implanted at an energy of 28 keV and a dose of 2.6×10¹⁶ ions/cm² through the strained layer and into the relaxed layer).

In this regard it is to be noted that, in one embodiment, other implanted species are used, such as H₂⁺, He⁺, or a combination thereof with the dose and energy being adjusted accordingly.

B. Handle Wafer Structure

Referring now to FIG. 1B, the handle wafer structure 11 comprises a handle wafer or substrate 16, which may optionally have a dielectric layer 15 on a surface thereof, which functions as an insulating layer in the final SSOI structure. The optional dielectric layer may be of any electrically insulating material suitable for use in an SSOI structure, such as for example a material comprising SiO₂, Si₃N₄, aluminum oxide, or magnesium oxide. In one preferred embodiment, the optional dielectric layer is SiO₂. However, it is to be noted that, in some instances, it may alternatively be preferred to use a material for the optional dielectric layer that has a melting point higher than the melting point of pure SiO₂, i.e., approximately 1700° C. Examples of such materials are silicon nitride (Si₃N₄), aluminum oxide, magnesium oxide, etc. Without being bound by a particular theory, it is generally believed that using a dielectric layer with a higher melting point may help prevent possible relaxation of the transferred strained layer, during subsequent processing, due to softening of the underlying optional dielectric layer at temperatures typically used during device fabrication, i.e., approximately 1000-1200° C.

The optional dielectric layer may be applied according to any known technique in the art, such as thermal oxidation, wet oxidation, or thermal nitridation. Generally speaking, the optional dielectric layer is grown to a substantially uniform thickness sufficient to provide the desired insulating properties in the final SSOI structure. Typically, the optional dielectric layer has an average thickness of at least about 10 nm, such as about 50 nm, about 100 nm, about 125 nm, about 150 nm, about 175 nm, or about 200 nm. Alternatively, the average thickness of the optional dielectric layer may be expressed as a range, such as between about 10 nm to about 200 nm, preferably between about 50 nm to about 175 nm, and even more preferably between about 100 nm to about 150 nm. In one preferred embodiment, the optional dielectric layer has a thickness of about 145 nm.

C. Wafer Bonding and Transfer of the Strained Layer

Once the donor wafer structure 10 and handle wafer structure 11 have been prepared, forming the final SSOI structure comprises transferring the strained silicon layer of the donor wafer structure onto the optional dielectric layer of the handle wafer structure. Generally speaking, this transfer is achieved by contacting the surface of the optional dielectric layer 15 to the surface of the thin SiO₂ layer 19 in order to form a single, bonded structure 20 with a bond interface 18 between the two surfaces, and then cleaving or separating the bonded structure along the separation or cleave plane 17 in the relaxed layer.

Prior to bonding, the surfaces of the thin SiO₂ layer of the donor wafer structure and/or the optional dielectric layer of the handle wafer structure may optionally undergo cleaning, a brief etching, and/or planarization to prepare their surfaces for bonding, using techniques known in the art. Without being bound by a particular theory, it is generally believed that the quality of the surface of the strained silicon layer in the final SSOI structure is, in part, a function of the quality of the surface prior to bonding. Additionally, the quality of both surfaces prior to bonding will have a direct impact on the quality or strength of the resulting bond interface.

The roughness of the surface is one way by which the surface quality is quantitatively measured, with lower surface roughness values corresponding to a higher quality surface. Therefore, the thin SiO₂ layer and/or the optional dielectric layer may undergo processing to reduce the surface roughness. For example, in one embodiment, the surface roughness is less than about 0.5 nm root mean square (RMS). This lowered RMS value can be achieved prior to bonding by cleaning and/or planarization. Cleaning may be carried out according to a wet chemical cleaning procedure, such as a hydrophilic surface preparation process. One common hydrophilic surface preparation process is a RCA SC1 clean process, wherein the surfaces are contacted with a solution containing ammonium hydroxide, hydrogen peroxide, and water at a ratio of, for example, 1:4:20 at about 60° C. for about 10 minutes, followed by a deionized water rinse and spin dry. Planarization may be carried out using a chemical mechanical polishing (CMP) technique. Further, one or both of the surfaces may be subjected to a plasma activation to increase the resulting bond strength before, after, or instead of a wet cleaning process. The plasma environment may include, for example, oxygen, ammonia, argon, nitrogen, diboran, or phosphine. In one preferred embodiment, the plasma activation environment is selected from the group consisting of nitrogen, oxygen, and combinations thereof.

Referring now to FIG. 2, the donor wafer structure is bonded to the handle wafer by bringing the surfaces of the thin SiO₂ layer 19 and the optional dielectric layer 15 together to form a bond interface 18. Generally speaking, wafer bonding may be achieved using essentially any technique known in the art, provided the energy employed to achieve formation of the bond interface is sufficient to ensure the integrity of the bond interface is sustained during subsequent processing, such as layer transfer by cleaving or separation. Typically, however, wafer bonding is achieved by contacting the surface of the thin SiO₂ layer and the optional dielectric layer at room temperature, followed by heating at an elevated temperature for a period of time sufficient to produce a bond interface having a bond strength greater than about 500 mJ/m², about 750 mJ/m², about 1000 mJ/m², or more. To achieve such bond strength values, heating typically takes place at temperatures of at least about 200° C., 300° C., 400° C., or even 500° C. for a period of time of at least about 5 minutes, 30 minutes, 60 minutes, or even 300 minutes.

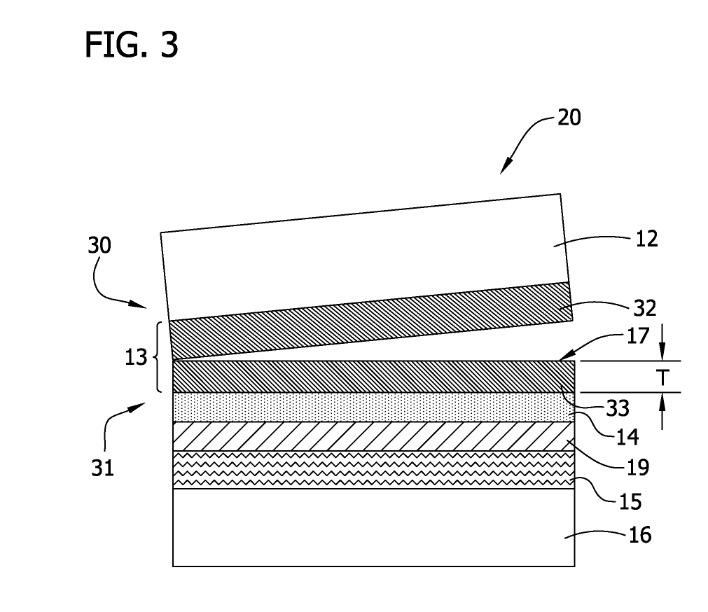

Referring now to FIG. 3, after the bond interface 18 has been formed, the resulting bonded structure 20 is subjected to conditions sufficient to induce a fracture along the separation or cleave plane 18 within the relaxed layer 13. Generally speaking, this fracture may be achieved using techniques known in the art, including, e.g., thermally-induced separation, mechanical separation, or a combination thereof. In one embodiment, annealing the bonded structure at an elevated temperature for a period of time can be employed to induce fracture. For example, the annealing temperature may be at least about 250° C., 350° C., 450° C., 550° C., 650° C., or even 750° C. Preferably, the temperature is between about 250° C. to about 750° C., and more preferably from about 350° C. to about 650° C. The anneal is performed over a time period of at least about 5 minutes, 30 minutes, 60 minutes, or even 300 minutes. Higher annealing temperatures will require shorter anneal times, and vice versa. The annealing step can be conducted in an ambient or inert atmosphere, e.g., argon or nitrogen.

Furthermore, another embodiment comprises inducing separation in the relaxed layer by mechanical force, either alone or in addition to the annealing process. The actual means of applying such a mechanical force is not critical to this invention; i.e., any known method of applying a mechanical force to induce separation in the relaxed layer may be employed, so long as substantial damage to the strained layer is avoided. In one preferred embodiment, mechanical force is used to induce separation in addition to an anneal of less than about 350° C.

Referring again to FIG. 3, two structures (30 and 31) are formed upon separation. If the separation of the bonded structure 20 occurs along the separation or cleave plane 17 in the relaxed layer 13, and the separation plane 17 does not coincide with the interface 18, but rather is present in the relaxed layer, a portion of the relaxed layer is part of both structures (i.e., a portion of the relaxed layer is transferred along with the strained layer). Structure 30 thus comprises the donor wafer 12 and some portion 32 of the relaxed layer 13, while structure 31 comprises the handle wafer 16, the optional dielectric layer 15, the thin SiO₂ layer 19, and the strained silicon layer 14 with a residual portion 33 of the relaxed layer 13 on the surface thereof.

In this regard it is to be noted that a residual portion 33 of the relaxed layer 13 is preferably present on the surface of the strained silicon layer 14 in order to, for example, ensure a thickness sufficient to withstand any subsequent processing that may be needed to remove damage resulting from the implantation step.

When present, the residual relaxed layer 33 has a thickness (T) that is approximately equivalent to the depth at which ions were implanted into the relaxed layer. Accordingly, this thickness (T) is typically greater than about 20, 30, 40 or even 50 nm. For example, in some instances the residual layer may optionally be at least about 65 nm, 75 nm, 85 nm, 100 nm, 150 nm, 200 nm thick or more. Preferably, the thickness (T) is sufficient to avoid damage to the strained layer upon separation; for example, in one preferred embodiment, the residual layer is between about 80 nm to about 90 nm thick.

2. Finishing the Strained Silicon Surface after Layer Transfer—Removal of Residual Relaxed Layer

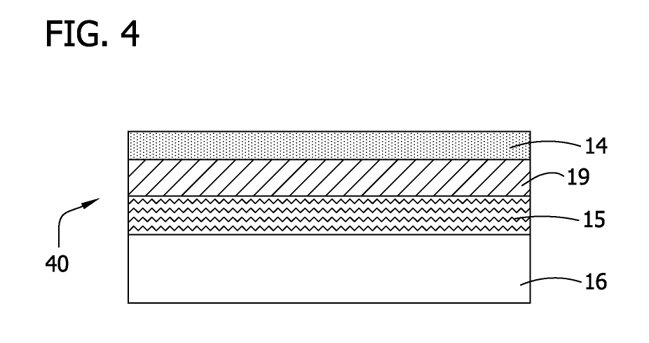

In accord with this invention and referring to FIGS. 3 and 4, after the strained silicon layer 14 has been transferred to the handle wafer 16 to form structure 31, structure 31 is subjected to additional processing to produce a strained silicon layer having desirable features for device fabrication thereon. For example, if a residual relaxed silicon-comprising layer 33 is present, structure 31 may be subjected to one or more processing steps in order to remove this residual layer. Any technique known in the art may be used to remove the residual layer, with the residual layer being removed preferably by etching. In one preferred embodiment, substantially all of the residual relaxed layer is removed via a wet etching process using an etchant comprising NH₄OH, H₂O₂, and H₂O. This etchant is available commercially in various formulations and is commonly referred to as an “SC1” solution.

In this regard it is to be noted that, as used herein, “substantially all” and/or “substantially free” refer to the essential absence of any detectable elements from the residual relaxed layer on the SSOI surface. For example, in one preferred embodiment, the strained silicon surface comprises no detectable Ge atoms, the detection limit thereof using means known in the art currently being about 1.0×10⁸ Ge atoms/cm².

Accordingly, the SSOI surface preferably comprises no detectable amount of any elements that were originally introduced to the strained layer to induce strain therein. For example, Ge is preferably removed to the fullest extent possible, as residual Ge may interfere with subsequent device fabrication or operation. Therefore, in accord with this invention, the strained silicon surface is substantially free of the relaxed layer. However, in some instances the surface may have some detectable amount of, for example, Ge present therein. In such instances, the strained silicon surface preferably comprises less than about 1.0×10¹⁰ Ge atoms/cm², such as less than about 7.5×10⁹ Ge atoms/cm², less than about 5.0×10⁹ Ge atoms/cm², less than about 2.5×10⁹ Ge atoms/cm², or even less than about 1.0×10⁹ Ge atoms/cm².

When etching is employed to remove the residual relaxed layer, the appropriate etching composition is selected according to various factors, including the precise composition of the residual relaxed layer and the selectivity of the etchant. Here, “selectivity” refers to the preferential rate at which the etchant removes the relaxed layer material in relation to the strained layer material. In one preferred embodiment, the selectivity of the etchant is evaluated with respect to the rate at which the relaxed SiGe layer is removed compared to the rate at which the strained silicon layer is removed. This ratio of SiGe:Si removal is at least in part dependent upon the concentration of Ge in the relaxed SiGe layer, as well as the etchant composition. Generally speaking, higher selectivity etchants are preferred so that the residual relaxed SiGe layer is removed quickly while retaining as much of the strained silicon layer as possible.

As previously noted, the concentration of Ge in the residual layer is at least about 10% Ge, and in some instances may be at least about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 35%, with a concentration of about 20% Ge being most preferred.

Typically, the etchant comprises NH₄OH, H₂O₂ and H₂O in a ratio sufficient to remove the residual relaxed SiGe layer from the handle wafer with a selectivity of SiGe:Si of at least about 3:1. Preferably, the etchant comprises NH₄OH, H₂O₂, and H₂O in a ratio sufficient to achieve a selectivity of at least about 3.5:1, more preferably at least about 4:1, still more preferably at least about 4.5:1, and even more preferably at least about 5:1 or more. In one preferred embodiment, a particularly preferred etchant comprises NH₄OH:H₂O₂:H₂O in a ratio of about 1:2:50.

Generally speaking, the duration of the etching process and the temperature at which the process takes place are sufficient to substantially remove the residual relaxed layer. The precise etching time depends on the thickness of the SiGe layer, which is in turn a function of the original ion implant energy. Typically, however, the handle wafer is exposed to the etchant for between about 1 minute to about 1000 minutes, such as between about 10 minutes to about 500 minutes, or about 20 minutes to about 200 minutes. Additionally, the handle wafer is typically etched at a temperature of between about 1° C. to about 100° C., such as between about 10° C. to about 90° C., and between about 50° C. to about 75° C., with longer etching times corresponding to lower temperatures and shorter etching times corresponding to higher temperatures. In one preferred embodiment, the etching takes place at about 65° C. for about 200 minutes.

During the etching process, agitation is typically applied to facilitate the removal of the residual relaxed SiGe layer, thereby enabling etching to be achieved over shorter durations. In one embodiment, megasonic agitation or treatment is employed at a power level typically ranging from about 5 to about 1500 watts. For example, the power of the megasonic etching may range from about 10 to about 1250 watts, from about 25 to about 1000 watts, from about 50 to about 750 watts, or from about 100 to about 500 watts.

As shown in FIG. 4, after removing the residual SiGe layer (when present), the resulting SSOI structure 40 comprises a silicon handle wafer 16, an optional dielectric layer 15 on a surface thereof, a silicon dioxide layer 19 on the surface of the optional dielectric layer (which, when the optional dielectric layer itself is silicon dioxide, may not be distinguishable from the optional dielectric layer), and a strained silicon layer 14 on the surface of the silicon dioxide layer. This SSOI structure may undergo any of several optional processing steps, such as, for example, an anneal to improve the crystallinity of the strained silicon layer (as disclosed, for example, in U.S. patent application Ser. No. 11/461,653, the entire contents of which is incorporated herein by reference for all relevant purposes).

3. Strained Silicon on Insulator Structure

The SSOI structure prepared in accordance with the present invention may have a substantially uniform thickness ranging from about 1 nm to about 100 nm thick. Preferably, in these or other embodiments, the strained Si layer has a thickness ranging from about 10 nm to about 80 nm, and more preferably from about 20 nm to about 60 nm thick.

Strained silicon-on-insulator structures manufactured according to this invention may be used in various technologies. For example, the SSOI structure of this invention is suitable for use in the manufacture of EMOS, PMOS, MOSFETs, FinFETs, CMOS, and bipolar-CMOS devices. This list is in no way intended to be restrictive or comprehensive.

The following Examples are simply intended to further illustrate and explain the present invention. The invention should not be limited to any of the details provided herein.

### EXAMPLE

A silicon donor wafer structure was prepared according to the invention by depositing a relaxed SiGe layer having an average thickness of about 0.2 μm via a commercial epitaxial deposition process utilizing a Ge-source gas and a Si-source gas. This was followed by applying a layer of silicon having an average thickness of about 80 nm thereon by means of epitaxial growth in an ASM Epislon 1 single wafer reactor. The silicon donor wafer was then subjected to an oxidation process, wherein the donor wafer was exposed to an atmosphere comprising steam at a temperature of about 800° C. for 360 seconds. This anneal produced a thin layer of SiO₂ that had an average thickness of about 50 Å on the surface of the strained silicon layer. A combination of hydrogen and helium ions were then implanted into the SiGe layer, through the strained silicon layer and the SiO₂ layer, to a depth of approximately 120 nm by an external implant service (Innovion Corporation), to create a separation plane within the relaxed SiGe layer.

Next, a silicon handle structure was prepared by growing a layer of SiO₂ 145 nm thick thereon by means of thermal oxidation in a vertical furnace at 850° C. for 120 minutes. The two structures were then bonded together, forming a bond interface between the thin layer of SiO₂ on the donor wafer and the thick SiO₂ layer on the handle wafer by means of N₂-plasma activation with an EAG bonder and hydrophilic bonding. Afterward, the bonded structure was subjected to a bond anneal at 300° C. for 60 minutes. Then, the structure was cleaved on a SiGen cleaver to cause separation along the implanted ion separation plane. One of the resulting structures comprised the handle wafer, the bonded SiO₂ layers, the strained silicon layer thereon, and a residual relaxed SiGe layer on the strained silicon layer, the residual relaxed layer having a thickness of about 105 nm. This structure was then exposed to NH₄OH:H₂O₂:H₂O etchant having a ratio of 1:2:50 for 240 minutes at about 65° C., while a megasonic treatment of about 1500 W was applied, in order to substantially remove the residual relaxed layer from the surface of the strained layer.

The above description of the preferred embodiments is intended only to acquaint others skilled in the art with the invention, its principles, and its practical application, so that others skilled in the art may adapt and apply the invention in its numerous forms, as may be best suited to the requirements of a particular use. The present invention, therefore, is not limited to the above embodiments, and may be variously modified.

With reference to the use of the word(s) “comprise” or comprises or “comprising” in this entire specification (including the claims below), it is noted that unless the context requires otherwise, those words are used on the basis and clear understanding that they are to be interpreted inclusively, rather than exclusively, and that it is intended each of those words to be so interpreted in construing this entire specification (including the claims).

What is claimed is:

1. A process for preparing a strained silicon on insulator structure, the method comprising:
forming a relaxed silicon-comprising layer on a surface of a donor wafer;
forming a strained silicon layer on the relaxed silicon-comprising layer;
forming a silicon dioxide layer on the strained silicon layer;
bonding the silicon dioxide layer on the donor wafer to the a handle wafer to form a bonded wafer, wherein a bond interface is formed between the silicon dioxide layer and the handle wafer;
separating the bonded wafer along a separation plane within the relaxed silicon-comprising layer to transfer the strained silicon layer to the handle wafer, such that the strained silicon layer on said handle wafer has a residual relaxed silicon-comprising layer on the surface thereof; and,
substantially removing the residual silicon-comprising layer to expose a surface of the strained silicon layer.

2. The process of claim 1 wherein the layer of SiO₂ is formed by annealing the surface of the strained silicon layer in an oxidizing atmosphere.

3. The process of claim 2 wherein the silicon on insulator structure is annealed at a temperature of at least about 700° C.

4. The process of claim 2 wherein the silicon on insulator structure is annealed at a temperature of at least about 800° C.

5. The process of claim 2 wherein the silicon on insulator structure is annealed at a temperature below about 900° c.

6. The process of claim 2 wherein the silicon on insulator structure is annealed at a temperature below about 850° C.

7. The process of claim 2 wherein the silicon on insulator structure is annealed at a temperature of from about 600° C. to about 900° C.

8. The process of claim 2 wherein the silicon on insulator structure is annealed at a temperature of from about 800° C. to about 850° C.

9. The process of claim 2 wherein the silicon on insulator structure is annealed for at least about 100 seconds.

10. The process of claim 2 wherein the silicon on insulator structure is annealed for at least about 300 seconds.

11. The process of claim 2 wherein the silicon on insulator structure is annealed for less than about 2000 seconds.

12. The process of claim 2 wherein the silicon on insulator structure is annealed from about 300 seconds to about 600 seconds.

13. The process of claim 1 wherein the layer of SiO₂ has an average thickness of at least about 50 Å.

14. The process of claim 1 wherein the layer of SiO₂ has an average thickness of at least about 100 Å.

15. The process of claim 1 wherein the layer of SiO₂ has an average thickness of at least about 150 Å.

16. The process of claim 1 wherein the layer of SiO₂ has an average thickness of at least about 200 Å.

17. The process of claim 1 wherein the handle wafer has a nominal diameter of 150 mm, 200 mm, or greater than 200 mm.

18. The process of claim 1 further comprising forming a dielectric layer on a surface of the handle wafer prior to forming the bonded wafer, and then bonding the silicon dioxide layer on the donor wafer to the dielectric layer on the handle wafer to form the bonded wafer, the bond interface being formed between the silicon dioxide layer and the dielectric layer of the handle wafer.

19. A strained silicon on insulator structure wherein the structure is formed according to the process of claim 1.

20. A single crystal silicon structure comprising:
a single crystal silicon substrate having a central axis, a front side and a back side which are generally perpendicular to the central axis, a circumferential edge, a radius extending from the central axis to the circumferential edge;
a relaxed silicon-comprising layer disposed on the front surface of the silicon substrate;
a strained silicon layer disposed on the relaxed silicon-comprising layer;
a layer of SiO₂ disposed on the strained silicon layer.

21. The structure of claim 20 wherein the single crystal silicon substrate has a nominal diameter of 150 mm, 200 mm, or greater than 200 mm.

22. The structure of claim 20 wherein the layer of SiO₂ has an average thickness of at least about 50 Å.

23. The structure of claim 20 wherein the layer of SiO₂ has an average thickness of at least about 100 Å.

24. The structure of claim 20 wherein the layer of SiO₂ has an average thickness of at least about 150 Å.

25. The structure of claim 20 wherein the layer of SiO₂ has an average thickness of at least about 200 Å.
